(19) United States
(12) Patent Application Publication
(10) Pub. No.: US 2004/0149224 A1
(43) Pub. Date: Aug. 5, 2004

(54) Gas tube end cap for a microwave plasma generator

(76) Inventor: Albert Wang, Moraga, CA (US)

Correspondence Address: KNOBBE MARTENS OLSON & BEAR LLP, 2040 MAIN STREET, FOURTEENTH FLOOR, IRVINE, CA, 92614, US

(21) Appl. No.: 10/651,433

(22) Filed: Aug. 29, 2003

Related U.S. Application Data
(60) Provisional application No. 60/408,013, filed on Aug. 30, 2002.

(51) Int. Cl. C23C 16/00

(52) U.S. Cl. 118/723 ME

(57) ABSTRACT

A plasma generator is provided with a plasma tube extending between a gas source and a process chamber, an end cap at one end of the plasma tube, and a seal extending around the plasma tube between the plasma tube and the end cap. The end cap includes a protrusion that extends into the plasma tube.

### CROSS REFERENCE TO RELATED APPLICATIONS

This application claims the benefit of U.S. Provisional Patent Application Serial No. 60/408,013, filed on Aug. 30, 2002, the entire content of which is incorporated herein by reference and made a part of the present disclosure.

### FIELD OF THE INVENTION

The present invention relates generally to microwave plasma generators and, more particularly, to gas inlet end caps for remote microwave plasma generators.

### BACKGROUND

Microwave plasma generators are widely used in the semiconductor industry. A typical microwave plasma generator includes a magnetron where microwave energy is generated, a series of waveguides through which the microwave energy travels, and an applicator where the microwave energy is applied to a process gas. Inside the applicator, the process gas receives microwave energy and starts to break down. A portion of the process gas turns into plasma, where a mixture of atoms, radicals, ions, and electrons coexist.

Plasma is generated at a location upstream and outside of the process chamber. The plasma products then flow through a plasma tube and enter the process chamber where a wafer is located for processing. The remoteness of the plasma source relative to the wafer results in reduced electrical damage to the wafers. Soon after the plasma is generated, ions, electrons and reactive radicals start to recombine to a lower energy state. Since ions and electrons are not desirable in low damage processes, the microwave plasma source is usually located away from the chamber to allow those charged particles to be neutralized before reaching the wafer. The length and material of the path is optimized to maximize recombination of charged particles but minimize recombination of neutral radicals, such that excited reactive species remain. The resultant low electrical damage of downstream plasma reactors, using remote microwave plasma sources, makes them a good choice for applications such as photoresist removal and advanced flip chip packaging.

An exemplary processing tool using a microwave plasma generator 10 is illustrated in FIG. 1. In the illustrated tool, process gases 12 enter the plasma generator 10 from above. Microwave energy 50 is applied to the process gases to generate a plasma. The plasma products flow through a plasma tube 16, pass through a baffle 18 (or a set of baffles) and flow into the process chamber 20 to a wafer 22. A vacuum pump (not shown) is attached to an exhaust port 24 of the chamber through a series of valves (not shown) and vacuum pipes (not shown) to remove the excess gas and by-product.

FIG. 2 illustrates a plasma generator 10 of the type used in the processing tool of FIG. 1. The illustrated generator 10 is designed for high power applications (e.g., up to 5 kW microwave power). A process gas mixture enters the plasma tube 16 through a gas inlet 28 in an end cap 30, where the gas lines 32, which are typically stainless steel or other metal, meet the end of the plasma tube 16, which is typically quartz, aluminum oxide, ceramic or sapphire. Sapphire is often preferred because it contains no impurities and is chemically stable for a wide range of chemistries. Sapphire is, however, expensive and prone to crack under even moderate temperature gradients.

Seals are located at the ends of the plasma tube 16 to provide leak tight joints. In the generator shown, a vacuum O-ring seal 40 (i.e., seal against the outside pressure differential) and a liquid O-ring seal 42 (i.e., seal against coolant leakage), which typically comprise an elastomer material, are provided around the outside of the plasma tube 16 at the process chamber end 44 of the plasma tube 16 and at the gas inlet end 46. The O-ring seals 40, 42 nearest the ends 44, 46 of the plasma tube 16 provide vacuum seals between the plasma tube 16 and the end cap 30 and between the plasma tube 16 and the process chamber (see FIG. 1), or chamber adapter 48 (the downstream analog to the upstream end cap 30).

Microwave power 50 is applied to the gas in a relatively small region of the plasma tube 16 that is adjacent a microwave cavity 52. Once a plasma 54 is generated by the microwave energy, the process gas temperature and the temperature of the plasma tube 16 tend to rise dramatically. If the plasma tube 16 gets too hot, failure of the plasma tube 16, or of the seals 40, 42 at the ends of the plasma tube 16, can result.

### SUMMARY OF THE INVENTION

Accordingly, a need exists for a plasma generator design in which the plasma tube and the seals at the end of the plasma tube are less susceptible to failure.

In accordance with one embodiment of the present invention, a plasma generator is provided with a plasma tube extending between a gas source and a process chamber, an end cap at one end of the plasma tube, and a seal extending around the plasma tube between the plasma tube and the end cap. The end cap includes a protrusion that extends into the plasma tube.

Another embodiment provides an inlet cap for use with a remote plasma generator. The cap comprises a gas interface configured to join the cap in fluid communication with a source of gases, an attachment interface configured for mounting the cap to an inlet end of a remote plasma generator, and a protrusion configured to extend into a lumen of a plasma tube. In one embodiment, the protrusion is formed integrally with the inlet cap. In another embodiment, the protrusion is sized to provide a small gap between the protrusion and the inner wall of the plasma tube. In one embodiment the gap between the protrusion and the inner wall of the plasma tube comprises an annular space between 0.127 mm and 0.254 mm wide.

### BRIEF DESCRIPTION OF THE DRAWINGS

These and other aspects of the invention will be readily apparent to the skilled artisan in view of the description below, the appended claims, and from the drawings, which are intended to illustrate and not to limit the invention, and wherein:

FIG. 1 is a simplified schematic illustration of a remote microwave plasma processing tool;

FIG. 2 is a simplified schematic illustration of the plasma generator of the processing tool of FIG. 1;

FIG. 3 is a simplified schematic illustration of the gas inlet end of the plasma generator of FIG. 2 in accordance with prior art teachings;

FIG. 4 is a simplified schematic illustration of the gas inlet end of a plasma generator having features and advantages in accordance with the present invention; and

FIG. 5 is a cross-sectional view of the gas inlet end of the plasma generator of FIG. 4 taken through line 5-5.

### DETAILED DESCRIPTION OF THE PREFERRED EMBODIMENTS

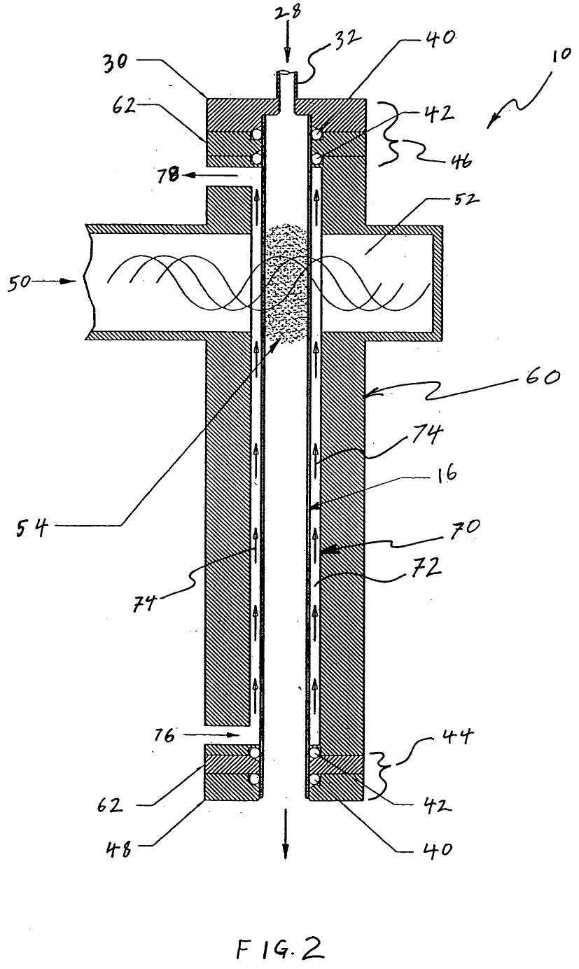

FIG. 2 illustrates an embodiment of a plasma generator 10. The illustrated generator 10 comprises a plasma tube 16, an outer body 60 surrounding the plasma tube 16, a gas inlet end cap 30, a vacuum seal 40, a cooling liquid seal 42, and a separation ring 62 between the seals 40, 42. A process gas mixture enters the plasma tube 16 through a gas inlet 28 in an end cap 30, where the gas lines 32, which are typically stainless steel or other metal, meet the end of the plasma tube 16, which is typically quartz, aluminum oxide, ceramic or sapphire. A section of the outer body 60 is configured to form a microwave cavity 52 into which microwave energy 50 can be introduced to generate plasma 54 from the gas mixture flowing into the plasma tube 16.

Various plasma generators 10 can include plasma tubes 16 with total lengths between about eight (8) inches (i.e. about 31.5 mm) and about 16 inches (i.e. about 63 mm). In the embodiment illustrated in FIG. 2, the plasma tube 16 has a length of about 14″. Additionally, in some embodiments, the plasma generator 10 is arranged such that the distance between the inlet end 46 of the plasma tube and the upper edge of the microwave cavity 52 is between about five (5) inches and about six (6) inches. Similarly, the plasma generator 10 can be arranged such that a distance between the upper edge of the microwave cavity 52 and the outlet end 44 of the plasma tube is between about eight (8) inches and about nine (9) inches. Of course, in further embodiments, dimensions outside of these ranges could also be used.

In order to control the temperature of the plasma tube 16, a cooling jacket 70 is provided to surround the plasma tube 16. The cooling jacket 70 comprises an annular space 72 through which a cooling fluid 74 can circulate between the outer body 60 and the plasma tube 16. The cooling jacket 70 generally includes a fluid inlet 76 connected to a fluid source (not shown) and a fluid outlet 78 in communication with a heat exchanger (not shown) for dissipating the heat absorbed by the cooling fluid 74. The cooling fluid 74 can be moved through the cooling jacket 70 and the other cooling system components by any suitable pump (not shown) as will be clear to the skilled artisan. The illustrated cooling jacket 70 is arranged in a “counter flow” arrangement, i.e. a cooling liquid 74 is circulated through the cooling jacket 70 with a flow in a linear direction that is opposite to the flow direction of the hot plasma. However, in alternative embodiments, the cooling fluid can be circulated through the cooling jacket 70 in a “parallel flow” arrangement.

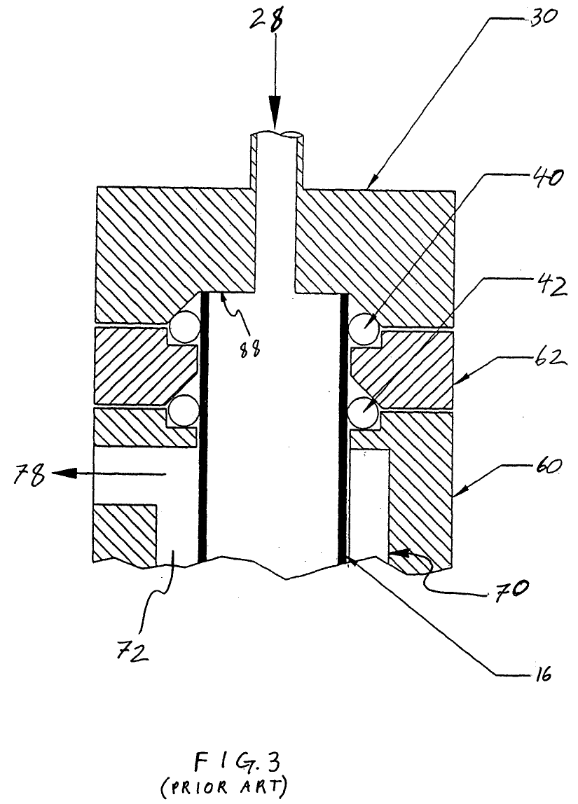

FIG. 3 illustrates an embodiment of a gas inlet end 46 of a plasma generator 10 in accordance with prior art teachings. The end cap 30, separation ring 62 and body 60 preferably are fastened together with screws (not shown). The end cap 30 of FIG. 3 comprises a recess 88 for receiving an upper portion of the plasma tube 16. The recess 88 is configured to abut the top annular edge of the plasma tube 16.

Cooling of the plasma tube 16 is an important design consideration. Liquid cooling is one commonly used means of cooling the plasma tube 16. With reference to FIG. 2, a pair of cooling liquid O-ring seals 42 are provided at either end adjacent the vacuum O-ring seals 40 to seal the cooling liquid 74 within the cooling jacket 70. Although the vacuum seals could conceivably be used to seal the cooling liquid within the cooling jacket as well, it is preferred to separate the functions of the two types of seals 40, 42. For air-cooled sources, however, the liquid seals could be omitted.

The most common failures in microwave plasma generators are O-ring seal failures and plasma tube failures. Plasma tube failures typically occur when the tube is subjected to temperature gradients that exceed the limits of the plasma tube material. These failures are often caused by improper or insufficient cooling of portions of the plasma tube and localized high density heat flux.

When sapphire plasma tubes fail, they often fail at the gas inlet end 46. In the generator of FIG. 2, the cooling liquid 74 provides sufficient cooling along the central portion of the plasma tube 16. However, the cooling liquid does not contact the ends 44, 46 of the plasma tube 16 beyond the liquid seals 42. In the generator of FIG. 2, the portions of the plasma tube 16 between the liquid seals 42 and the vacuum seals 40 are cooled primarily by heat transfer through the separation ring 62. Any gaps between the plasma tube 16 and the separation ring 62 will reduce the heat transfer rate between the plasma tube 16 and the separation ring 62 by preventing or reducing conductive heat transfer. Convective heat transfer is also substantially reduced under vacuum conditions due to the lack of gaseous molecules to transfer the heat from the end cap 30 of the plasma tube 16 to the separation ring 62.

O-ring seal failures typically occur when the surface of the plasma tube 16 exceeds the O-ring material service temperature. Material incompatibility can also be a source of O-ring failure, although recent advances in perfluoroelastomer materials (e.g., Chemrez™ or Kalrez™ O-rings) have largely reduced the likelihood of material incompatibility failures. A number of different high temperature elastomer O-rings have been used, but none has survived with a reasonable service life span. Aluminum O-rings have also been substituted for the elastomer vacuum O-ring seals, but with limited success. The difference in coefficients of thermal expansion between the sapphire plasma tube and the aluminum O-rings and O-ring grooves makes it very difficult for them to work together properly. Metal O-rings can also be difficult to assemble correctly.

Good heat-sinking helps keep the overall temperature of the O-rings lower and consequently improves the performance and service life of the O-rings. However, some high power processes generate so much heat that the plasma tube temperature can nonetheless exceed the O-rings' specifications. Additionally, as described above, the liquid cooling stops at the cooling liquid seals. The ends of the plasma tube beyond the liquid seals are not actively cooled by the cooling liquid and can reach temperatures well above the specifications of the best high temperature elastomer O-rings. The vacuum seals are thus easily burned and damaged under high temperature conditions.

In high power microwave generators of the type illustrated in FIG. 2, all of the O-rings 40, 42 are in direct contact with the plasma tube 16 and are thus subject to high temperatures. It has been observed, however, that the cooling liquid seals 42 usually outlast the vacuum seals 40. This is likely due to the fact that portions of the cooling liquid seals 42 can be in direct contact with the cooling liquid 74. The cooling liquid 74 removes heat efficiently and thus lowers the seal temperature. In contrast, the cooling liquid 74 does not directly contact the vacuum seals 40. Instead, the vacuum seals 40 are contacted, in the generator of FIG. 2, by the separation ring 62 and the gas inlet end cap 30, which are typically made of aluminum and serve as heat sinks for the vacuum seals. Since the convective heat transfer of the cooling liquid contact adjacent the liquid seals 42 removes heat at a higher rate than the heat transfer through the indirect contact of the tube 16 or separation ring 62 adjacent the vacuum seals 40, the liquid seals 42 receive much better heat-sinking than the vacuum seals 40 and usually last longer.

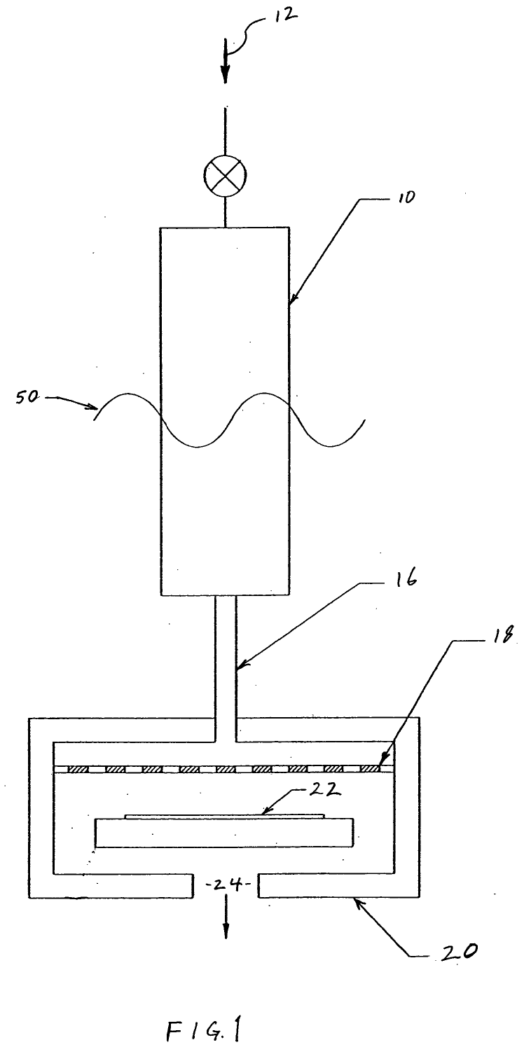

It has further been observed that the seals 40, 42 at the gas inlet end 46 of the plasma tube 16 (which is illustrated in greater detail in FIG. 3) usually do not last as long as the seals 40, 42 at the process chamber end 44 of the plasma tube 16. The hottest part of the plasma tube 16 is the section adjacent the microwave cavity 52, where the plasma 54 is generated by the application of microwave energy 50. In remote microwave plasma generators, the microwave cavity 52 is located some distance from the process chamber 20 (see FIG. 1). Accordingly, the O-ring seals 40, 42 at the gas inlet end 46 are usually much closer to the hottest region of the plasma tube 16, and are thus subjected to higher temperatures than the O-ring seals 40, 42 at the chamber end 44. Although the applicator could be designed so that the seals at the gas inlet end are just as far away from the microwave cavity as the seals at the chamber end, that would require a much longer plasma tube in order to achieve the desired distance between the point at which the plasma is generated, and the processing chamber. For quartz and ceramic tubes, longer tubes are not too difficult to manufacture. But for single crystal sapphire tubes, which have to be grown from a crucible, long tubes are expensive and very difficult to manufacture. They tend to be either not very straight or the crystal structure becomes unstable at the end. For a practical and economical design, the sapphire plasma tube should be as short as possible while meeting the low electrical damage requirement.

In addition, it has been observed that the direction of the cooling liquid flow in the cooling jacket 70 also affects seal life. As discussed above, the illustrated cooling system is configured in a counter flow arrangement such that the cold cooling liquid enters the cooling jacket 70 at a point adjacent the chamber end 44 of the plasma tube 16, and heated liquid exits at an upper end of the cooling jacket 70 that is adjacent the inlet end 46 of the plasma tube 16. Typically, the cooling liquid 74 is circulated through a coolant-to-water heat exchanger (not shown) to dissipate the heat absorbed by the cooling liquid 74. The end of the plasma tube 16 adjacent the cooling liquid inlet 76 is usually cooler, and the seals 40, 42 at that end usually last longer.

If the plasma generator 10 is located directly above the process chamber, as in FIGS. 1 and 2, the cold liquid enters the cooling jacket near the bottom (i.e., the process chamber end) of the plasma tube 16 so that the air bubbles can be eliminated from the liquid. If the cold liquid enters near the top (i.e., the gas inlet end) of the plasma tube, air pockets may be formed at the top of the cooling jacket and seriously compromise the local heat transfer. Thus, the cold liquid enters near the bottom of the plasma tube, picks up heat along the length of the plasma tube, and exits warmer near the top of the plasma tube. As a result, the seals at the gas inlet end 46 of the plasma tube 16 receive less cooling because the liquid at that end has already absorbed heat from the plasma generation.

As semiconductor processing equipment has moved from 200 mm to 300 mm wafer designs, plasma source power has been increased to keep the process results in pace. For example, a 3 kW power source may be used in 200 mm machines, while a 5 kW power supply may be used in 300 mm machines. Because of the higher power, plasma tube and seal failures occur even more frequently in 300 mm machines.

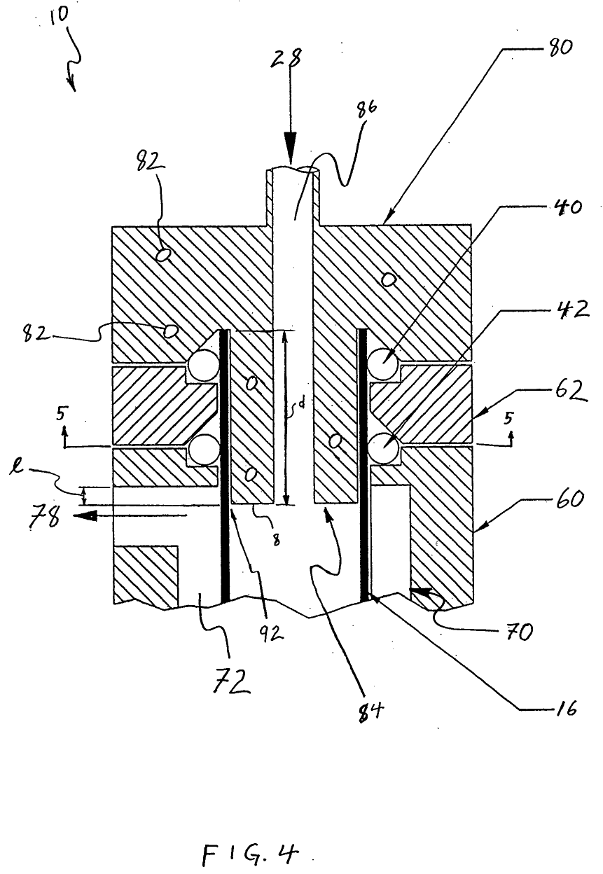

FIG. 4 illustrates one embodiment of a gas inlet end 46 of a plasma generator 10 having features and advantages in accordance with the present invention. In the illustrated embodiment, the plasma generator 10 includes a plasma tube 16, an outer body 60 surrounding the plasma tube 16, a gas inlet end cap 80, a vacuum seal 40, a coolant seal 42, and a separation ring 62 between the seals. In the illustrated embodiment, the seals 40, 42 are O-rings. The end cap 80, separation ring 62 and outer body 60 preferably are fastened together with screws (not shown), however other attachment systems and methods may alternatively be used. A cooling jacket 70 within which a cooling fluid 74 can be circulated is formed between the outer body 60 and the plasma tube 16.

Those skilled in the art will recognize that, in alternative embodiments, a single seal could perform the functions of both the vacuum seal and the coolant seal. The separation ring could then also be eliminated. However, as described above, it is preferable to use both the vacuum seal and the coolant seal to prevent the serious damage that might otherwise occur, such as leakage of cooling fluid into the process chamber, in the event of failure of a single seal.

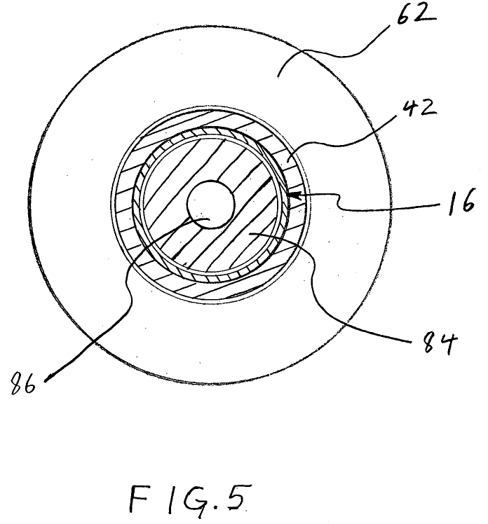

As illustrated in FIGS. 4 and 5, the end cap 80 has a protrusion 84 that extends into the plasma tube 16. The protrusion 84 preferably is tubular (i.e. it has a solid wall surrounding a hollow longitudinal center) and is configured to conform to the shape of the inside of the plasma tube 16. The end cap 80 and the protrusion 84 preferably comprise a lumen 86 extending therethrough in order to provide a gas passage through the end cap 80 and the protrusion 84.

The end cap 80 can also be provided with a suitable interface (not shown) for joining the lumen 86 in fluid communication with a source of a suitable gas mixture. Such an interface can include any structure recognized by the skilled artisan as suitable. For example, the end cap interface might simply include a threaded hole to which a threaded connector can be attached for supplying a gas to the plasma generator 10.

The protrusion 84 can comprise any cross-sectional shape in order to conform to the plasma tube 16. For example, the protrusion 84 is most often cylindrical, however it could alternatively comprise triangular, rectangular or other polygonal cross-sectional shapes.

Preferably, the protrusion 84 extends inwardly into the plasma tube 16 by a sufficient distance ‘d’ that the distal end 87 of the protrusion extends at least beyond the vacuum seal 70, and in one preferred embodiment the protrusion 84 extends between about 0.25 inches to 0.5 inches downstream of the coolant seal 42. In the embodiment shown, the protrusion 84 extends into the plasma tube 16 a sufficient distance ‘d’ so that the end 87 of the protrusion 84 overlaps the cooling jacket 70 by a distance ‘l’. In some embodiments, the distance ‘d’ can be about two to three inches. The distance ‘l’ can be varied depending on various factors such as the amount of heat desired to be transferred through the inlet cap. For example, in some embodiments, the distance ‘l’ can be between about 0.125″ (3.175 mm) and about 0.875″ (22.225 mm), and in other embodiments the distance ‘l’ can be between about 0.25″ (6.35 mm) and about 0.75″ (19.05 mm). In one preferred embodiment, the distance ‘l’ is about 0.5″ (1.27 mm). Dimensions outside of these ranges can also be used depending on factors such as the dimensions of the plasma generator components.

The protrusion is sized so that a gap 92 is formed between the protrusion 84 and the inner surface of the plasma tube 16. The gap 92 preferably is as small as possible, while allowing for thermally-induced expansion and contraction of the tube 16 and the end cap 80 relative to one another. The end cap 80 and protrusion 84 are preferably made of a metal. For example, in one embodiment aluminum is preferred because of its high thermal conductivity. The aluminum may be anodized for corrosion resistance. Alternatively, however, the end cap and protrusion may comprise a ceramic material, such as aluminum oxide or aluminum nitride, or any other suitable material. The plasma tube 16 preferably comprises sapphire; however, as discussed above, other materials such as quartz or ceramic can alternatively be used. If the protrusion 84 and the end cap 80 are aluminum and the plasma tube 16 is sapphire, as in the illustrated embodiment, the gap 92 between the protrusion and the inner surface of the plasma tube 16 is preferably between about 5 mils (i.e. 0.005 inch or 0.127 mm) and 10 mils (0.254 mm).

According to one preferred embodiment, the protrusion 84 is formed integrally with the end cap 80 as a single piece, as in the illustrated embodiment, so as to increase the rate of heat transfer between the protrusion 84 and the rest of the end cap 80. Alternatively, the protrusion 84 may comprise a separate part that is fastened to the rest of the end cap 80, such as with screw threads.

Typically, some amount of heat will be transferred directly to the protrusion 84 and through the end cap 80 to the environment outside of the plasma generator. If desired, the cap 80 can be provided with additional cooling structures such as heat fins and/or cooling fans. In still further embodiments, portions of the end cap 80 may be configured to be fluid-cooled by circulating a fluid, such as water, air, or other suitable fluid, through fluid passages 82 formed in the end cap 80 to more effectively remove heat from the end cap.

The protrusion 84 of the end cap 80 advantageously provides a better heat sink for the plasma tube 16 and the seals 40, 42. In addition, the protrusion 84 effectively blocks the plasma generated within the plasma tube 16 from reaching the inner surface of the plasma tube 16 at the gas inlet end 46, thereby blocking the path of heat flux from the plasma and reducing the amount of heating of the inlet end of the plasma tube 16.

Since the gap 92 between the protrusion 84 and the plasma tube 16 is small, plasma practically ceases to exist in the gap 92. The mean free path of the gas molecules at the process pressure is much greater than the gap distance. Any gas particles entering the gap collide frequently and rapidly with the protrusion 84 and the inner surface of the plasma tube 16, thereby losing energy. As a result, plasma can only exist a very short distance into the gap 92. Accordingly, by blocking plasma from the end of the plasma tube 16, and by providing a better heat sink for the plasma tube 16 and the O-ring seals 40, 42, the end cap 80 of the illustrated embodiment effectively and advantageously prevents the plasma tube 16 and the seals 40, 42 from being damaged under extreme heat load conditions.

Although this invention has been disclosed in the context of certain preferred embodiments and examples, it will be understood by those skilled in the art that the present invention extends beyond the specifically disclosed embodiments to other alternative embodiments and/or uses of the invention and obvious modifications and equivalents thereof. For example, the above teachings could alternatively be applied to the outlet cap (chamber adapter) 48 of FIG. 2 by providing a similar protrusion thereto. It is further contemplated that various combinations and sub-combinations of the specific features and aspects of the embodiments may be made and still fall within the scope of the invention. It is intended that the scope of the present invention herein disclosed should not be limited by the particular disclosed embodiments described above, but should be determined only by a fair reading of the claims that follow.

It should be noted that certain objects and advantages of the invention have been discussed above for the purpose of describing the invention and the advantages achieved over the prior art. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

I claim:

1. A plasma generator comprising a plasma tube extending between a gas source and a process chamber, an end cap at one end of the plasma tube, and a seal extending around the plasma tube between the plasma tube and the end cap, the end cap comprising a protrusion extending into the plasma tube.

2. The plasma generator of claim 1, wherein the protrusion extends into the plasma tube beyond the seal.

3. The plasma generator of claim 2, wherein the end cap is located at an upstream end of the plasma tube.

4. The plasma generator of claim 3, further comprising a cooling jacket surrounding the plasma tube, the cooling jacket adapted to contain a cooling fluid circulating through the cooling jacket to cool the plasma tube, and wherein the protrusion extends into the plasma tube to overlap the cooling jacket.

5. The plasma generator of claim 4, further comprising a second seal extending around the plasma tube between the plasma tube and the end cap, the second seal adapted to seal the cooling fluid within the cooling jacket.

6. The plasma generator of claim 5, wherein the protrusion extends into the plasma tube beyond the second seal.

7. The plasma generator of claim 6, wherein the protrusion extends into the plasma tube between about 0.25 inches (6.35 mm) and 0.5 inches (12.7 mm) downstream of the second seal.

8. The plasma generator of claim 8, wherein the seals comprise O-rings.

9. The plasma generator of claim 1, wherein a gap of between about 0.127 mm and 0.254 mm is provided between the protrusion and an inner surface of the plasma tube.

10. The plasma generator of claim 9, wherein the protrusion is formed integrally with the end cap.

11. The plasma generator of claim 10, wherein the end cap comprises fluid passages to allow a cooling fluid to be circulated through the end cap to cool the end cap.

12. The plasma generator of claim 11, wherein the protrusion comprises a metal.

13. The plasma generator of claim 12, wherein the metal is aluminum.

14. A remote microwave plasma generator, comprising a plasma tube having an inlet end and an outlet end, and an insert extending into the inlet end and conforming closely to an inner surface of the plasma tube.

15. The plasma generator of claim 14, wherein the plasma tube comprises sapphire.

16. The plasma generator of claim 15, wherein the insert comprises aluminum.

17. The plasma generator of claim 16, wherein a gap of between about 5 mils (0.127 mm) and 10 mils (0.254 mm) separates the insert and the inner surface of the plasma tube.

18. The plasma generator of claim 14, wherein the insert is integrally formed with an inlet cap.

19. An inlet cap for use with a remote plasma generator, the cap comprising:
a gas interface configured to join the cap in fluid communication with a source of gases;
an attachment interface configured for mounting the cap to an inlet end of a remote plasma generator; and
a protrusion configured to extend into a lumen of a plasma tube.

20. The inlet cap of claim 19, wherein the protrusion is sized to leave a gap between the protrusion and an inner wall of the plasma tube.

21. The inlet cap of claim 19, wherein the protrusion is configured to extend into the plasma tube to a point beyond a seal located on an outer surface of the plasma tube to maintain a pressure differential between the inside of the plasma tube and the environment outside of the plasma generator.

22. The inlet cap of claim 21, wherein the protrusion is configured to extend into the plasma tube to a portion of the tube surrounded by a cooling jacket.

23. The inlet cap of claim 21, wherein the cap is configured to be actively cooled.

24. The inlet cap of claim 19, wherein the protrusion is integrally formed with the inlet cap.
